(19) United States
(12) Patent Application Publication
(10) Pub. No.: US 2012/0211783 A1
(43) Pub. Date: Aug. 23, 2012

(54) LIGHT-EMITTING-DIODE ARRAY WITH MICROSTRUCTURES IN GAP BETWEEN LIGHT-EMITTING-DIODES

(75) Inventors: Ray-Hua Horng, Taichung City (TW); Yi-An Lu, Chiayi City (TW); Pei-Yun Kuo, New Taipei City (TW)

(73) Assignees: NCKU RESEARCH AND DEVELOPMENT FOUNDATION, Tainan City (TW); PHOSTEK, INC., Taipei City (TW)

(21) Appl. No.: 13/462,777

(22) Filed: May 2, 2012

Related U.S. Application Data
(63) Continuation-in-part of application No. 12/948,504, filed on Nov. 17, 2010, now Pat. No. 8,193,546.

(51) Int. Cl. H01L 33/08

(52) U.S. Cl. 257/93; 438/34; 257/E33.012

(57) ABSTRACT

A light-emitting-diode (LED) array includes a first LED device having a first electrode and a second LED device having a second electrode. The first LED device and the second LED device are positioned on a common substrate. At least one polymer material is between the first LED device and the second LED device. A plurality of microsctructures are in the at least one polymer material. An interconnect is formed on top of the at least one polymer material to electrically connect the first electrode and the second electrode.

### PRIORITY CLAIM

This patent application is a continuation-in-part of U.S. patent application Ser. No. 12/948,504 entitled “LIGHT-EMITTING-DIODE ARRAY AND METHOD FOR MANUFACTURING THE SAME” to Horng et al. filed on Nov. 17, 2010.

### BACKGROUND

1. Field of the Invention

The present invention relates to a semiconductor light emitting component, and more particularly to a light emitting diode (LED) array and a method for manufacturing the LED array.

2. Description of Related Art

A light-emitting diode (LED) is a semiconductor diode based light source. When a diode is forward biased (switched on), electrons are able to recombine with holes within the device, releasing energy in the form of photons. This effect is called electroluminescence and the color of the light (corresponding to the energy of the photon) is determined by the energy gap of the semiconductor. When used as a light source, the LED presents many advantages over incandescent light sources. These advantages include lower energy consumption, longer lifetime, improved robustness, smaller size, faster switching, and greater durability and reliability.

FIG. 1 is a perspective view of LED die 100. LED die 100 includes a substrate 102, an N-type layer 110, a light-emitting layer 125, and a p-type layer 130. N-contact 115 and p-contact 135 are formed on the n-type layer 110 and the p-type layer 130, respectively, for making electrical connections thereto. When a proper voltage is applied to the n-and p-contacts 115 and 135, electrons depart the n-type layer 110 and combine with holes in the light-emitting layer 125. The electron-hole combination in the light-emitting layer 125 generates light. Sapphire is a common material for the substrate 102. The n-type layer 110 may be made of, for example, AIGaN doped with Si or GaN doped with Si. The p-type layer 240 may be made of, for example, AIGaN doped with Mg or GaN doped with Mg. The light emitting layer 125 is typically formed by a single quantum well or multiple quantum wells (e.g., InGaN/GaN).

In some cases, a series or parallel LED array is formed on an insulating or highly resistive substrate (e.g., sapphire, SiC, or other III-nitride substrates). The individual LEDs are separated from each other by gaps, and interconnects deposited on the array electrically connect the contacts of the individual LEDs in the arrays. Typically, to ensure complete electrical isolation of individual LEDs, a dielectric material is deposited over the LED array before forming the interconnects, then the dielectric material is patterned and removed in places to open contact holes on n-type layer and p-type layer. Dielectric material is left in the gap between the individual LEDs on the substrate and on the mesa walls between the exposed p-type layer and n-type layer of each LED. Dielectric material may be, for example, oxides of silicon, nitrides of silicon, oxynitrides of silicon, aluminum oxide, or any other suitable dielectric material.

However, deposition of dielectric material is a slow and costly process. Moreover, subsequently formed interconnects may pose reliability concerns due to complex profiles and sharp corners of the interconnects. As such, what is desired is a system and method for manufacturing an LED array device cost-effectively and with improved long term reliability.

### SUMMARY

In certain embodiments, a light-emitting-diode (LED) array includes a first LED device having a first electrode and a second LED device having a second electrode. The first LED device and the second LED device are positioned on a common substrate. At least one polymer material is between the first LED device and the second LED device. A plurality of microsctructures are in the at least one polymer material. An interconnect is positioned on top of the at least one polymer material to electrically connect the first electrode and the second electrode.

In certain embodiments, a method for forming a light-emitting-diode (LED) array includes forming an LED structure on a substrate and dividing the LED structure into at least a first LED device and a second LED device. At least one polymer material is deposited between the first LED device and a second LED device. The at least one polymer material includes a plurality of microsctructures. An interconnect is formed on top of the at least one polymer material to electrically connect a first electrode of the first LED and a second electrode of the second LED.

### BRIEF DESCRIPTION OF THE DRAWINGS

Features and advantages of the methods and apparatus of the present invention will be more fully appreciated by reference to the following detailed description of presently preferred but nonetheless illustrative embodiments in accordance with the present invention when taken in conjunction with the accompanying drawings in which:

FIG. 1 is a perspective view of an LED die.

FIGS. 2A and 2B depict schematic, top views of embodiments of light emitting diode arrays formed on a single substrate.

FIG. 3 depicts a schematic, partial, cross-sectional view of the LED array shown in FIG. 2B.

FIGS. 4A-4C depict an embodiment of a process for forming an LED array that uses a polymer to fill up a gap between LED devices.

FIG. 5 illustrates an embodiment of an LED array with a trench formed in the substrate between two LED devices.

FIGS. 6A and 6B illustrate some alternative embodiments of interconnect patterns.

FIG. 7 illustrates an embodiment of an LED chip flip mounted on a board.

FIG. 8 depicts an embodiment of an LED array with spherical microstructures in the polymer material filling the gap between two LED devices.

FIG. 9 depicts an embodiment of an LED array with pyramid microstructures in the polymer material filling the gap between two LED devices.

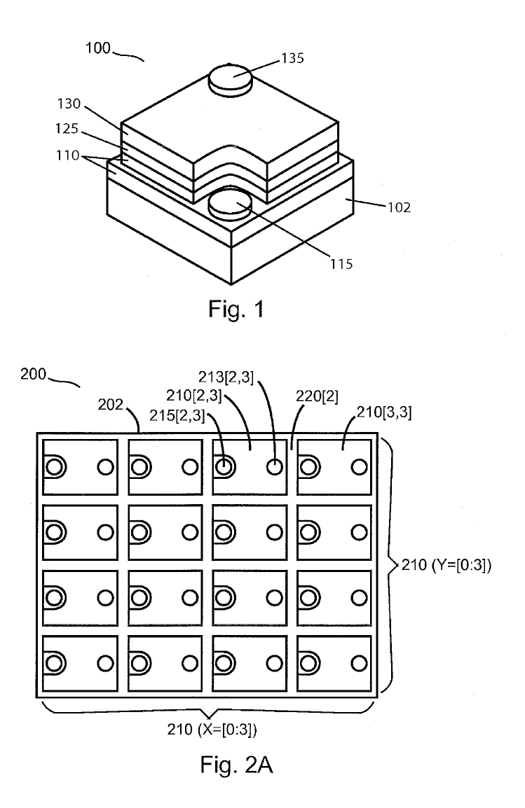

While the invention is susceptible to various modifications and alternative forms, specific embodiments thereof are shown by way of example in the drawings and will herein be described in detail. The drawings may not be to scale. It should be understood that the drawings and detailed description thereto are not intended to limit the invention to the particular form disclosed, but to the contrary, the intention is to cover all modifications, equivalents and alternatives falling within the spirit and scope of the present invention as defined by the appended claims.

### DETAILED DESCRIPTION OF EMBODIMENTS

The present invention discloses an LED array structure and a process method for manufacturing the LED array. The LED array is formed from multiple LED devices for producing significant amounts of light at relatively low current density. Low current density generates less heat and allows polymer materials to be used in the LED array. Details of the LED array structure and the process for manufacturing the LED array are described hereinafter.

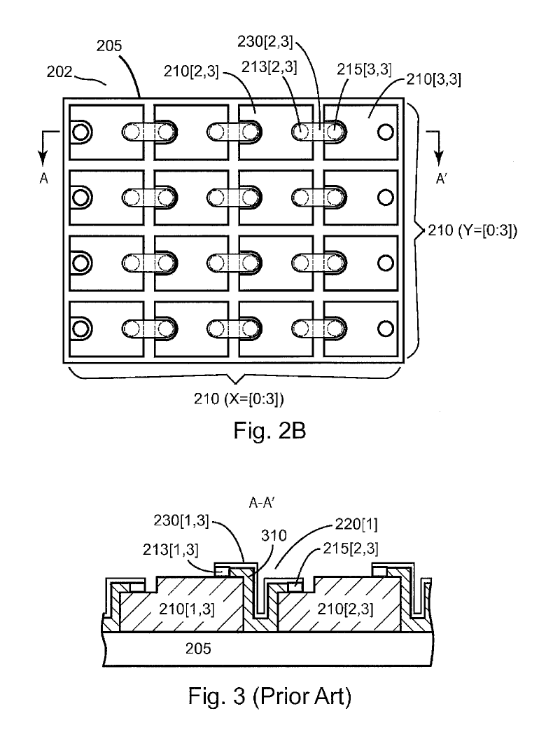

FIGS. 2A and 2B depict schematic, top views of embodiments of light emitting diode arrays 200 formed on single, common substrate 205. Referring to FIG. 2A, LED array 200 includes a number of light emitting diode (LED) devices 210 arranged in rows and columns. In the depicted embodiment, LED devices 210 are arranged in, but not limited to, four rows and in four columns. The numeral [X, Y] represents a position of LED device 210 in X column and in Y row (X=0, 1, 2, 3; Y=0, 1, 2, 3). Thus, the numeral [0:3, 0:3] can represent LED devices 210 in all positions of the LED array 200. Each of LED devices 210 has a mesa-shaped configuration. LED devices 210 are spatially separated from each other by either a laser etching method, a dicing or cutting saw, or an inductively coupled plasma reactive ion etching (ICP-RIE) method. For example, gap 220[2] is formed between neighboring LED devices 210[2, 3] and 210[3, 3]. LED devices 210 typically have two electrodes. For example, LED device 210[2,3] has two electrodes (e.g., pads 213[2, 3] and 215[2, 3]) serving as an anode and a cathode, respectively, of the LED device. The electrodes can be formed on p-GaN and n-GaN (either p-side up or n-side up). One LED device's anode pad is placed close to a neighboring LED device's cathode pad such that LED devices 210 can be easily connected in series.

Referring now to FIG. 2B, pad 213[2, 3] and pad 215[3, 3] are connected by interconnect 230[2,3]. Pads 213, 215, as well as interconnect 230, are typically formed by a metal. Pads 213, 215 and interconnect 230 may not necessarily be formed by the same metal.

FIG. 3 depicts a schematic, partial, cross-sectional view of LED array 202 at a location A-A′ shown in FIG. 2B. On single substrate 205, multiple LED devices 210 are built with cross-sections of two adjacent ones, 210[1, 3] and 210[2, 3], shown in FIG. 3. Pad 213[1, 3], for example, is an anode of LED device 210[1, 3] and pad 215[2, 3] is a cathode of LED device 210[2, 3]. Conventionally, oxide layer 310 is formed in gap 220[1] between LED devices 210 to electrically isolate pads 213 and 215 from adjacent structures. Then, metal interconnect 230[1, 3] is formed on top of oxide layer 310 to connect pads 213[1, 3] and 215[2, 3]. Because of the depth of gap 220, however, oxide layer 310 can not fully fill the gap. Further, the profile of metal interconnect 230 is complicated and has a number of sharp corners. Thus, metal interconnect 230 is prone to being broken and the reliability of conventional light emitting diode array 400 is reduced.

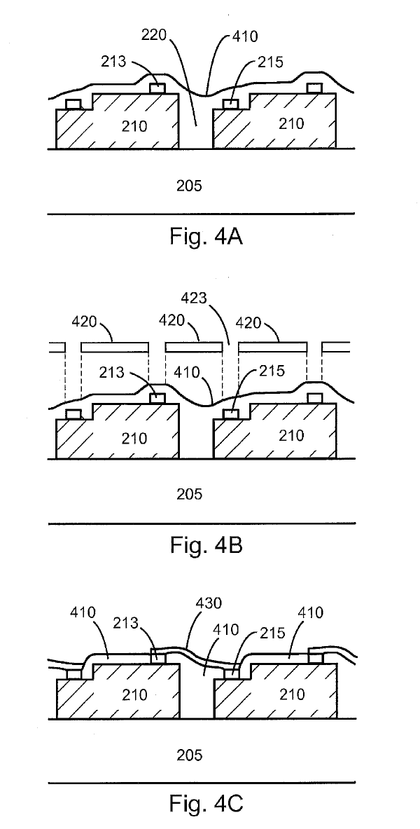

FIGS. 4A-4C depict an embodiment of a process for forming an LED array that uses a polymer to fill up gap 220 between LED devices 210. Because the LED devices described herein are intended to be used at high efficiency with little heat generated, it is feasible to leave polymer material in a finished LED device.

Beginning with FIG. 4A, after each individual LED device 210 and respective pads 213 and 215 are formed, polymer layer 410 is deposited over the LED devices. The polymer layer 410 fills up gap 220. Polymer 410 may be photoresist, such as polymethylglutarimide (PMGI) or SU-8. In certain embodiments, the refractive index of polymer layer 410 ranges from 1 to 2.6 (between air and semiconductor) to enhance light extraction. Optical transparency of polymer layer 410 may be equal to or more than 90% (e.g., equal to or more than 99%). Typically, a thickness of polymer layer 410 measured on top of anode 308 is approximately 2 microns. In some embodiments, polymer layer 410 is pre-mixed with phosphor (about 30 weight percentage loading) to adjust the output light color. However, the relative dimension between polymer coating thickness and phosphor particle size should be coordinated. For example, when a thickness of polymer layer 410 at pad 213 is about 3 microns, proper phosphor particle size is approximately 3 microns or less.

Next, as shown in FIG. 4B, patterned mask 420 is applied over polymer layer 410. Mask 420 may have openings 423 at the locations of pads 213 and 215 to allow the removal of polymer layer 410 thereon. In some embodiments, the polymer removal process smooths out the surface profile of polymer layer 410.

After the polymer removal process and pads 213 and 215 are exposed, a surface hydrophilic modification is performed on the polymer surface (e.g., oxygen plasma) to transform the originally hydrophobic surface into hydrophilic surface. Therefore, a subsequently formed metal-based interconnect can have improved adhesion to polymer layer 410.

Subsequently, as shown in FIG. 4C, interconnect 430 is formed on top of polymer layer 410 to connect pad 213 and pad 215. In certain embodiments, pad 213 and pad 215 have different vertical heights above the surface of substrate 205. Because of the smooth surface profile of polymer layer 410, the subsequently formed metal-based interconnect 430 may have a thin and smooth profile with improved endurance. The thin and smooth profile may provide improved performance and reliability as compared to the conventional interconnect with complex profiles and sharp corners depicted in FIG. 3. Even though the fragileness of the conventional interconnect 230 can be slightly improved by increasing the thickness of the interconnect 230, this is done at increased cost due to both additional material used and additional processing time.

In certain embodiments, as mentioned above, LED devices 210 are intended to be used at high efficiency with little heat generated. Thus, metals with lower melting points, such as Al, In, Sn, or related alloy metals can be used to form the major component of interconnect 430 (equal to or more than 90 vol %). Using such metal may further lower the cost of producing LED array 200. Fabrication processes, such as chemical vapor deposition, sputtering, or evaporation of the metal, can be used for forming interconnect 430. In one embodiment, three layers of metal (Ti/Al/Pt) are sputtered to form interconnect 430.

In some embodiments, a mixture of metal powder and polymer (e.g. silver paste) is used to form interconnect 430. A corresponding fabrication process may be a screen printing or a stencil printing process with even lower manufacturing cost.

In certain embodiments, the smoothness of polymer layer 410 allows the sizes of the pads 213, 215 and interconnect 430 to be smaller than the conventional ones shown in FIG. 3. Reducing the sizes of the pads and interconnect may provide less shielding of the LED area.

In addition to the aforementioned providing a smooth surface, in some embodiments, polymer layer 410 absorbs and dissipates heat from neighboring LED devices 210. Mixing polymer layer 410 with some special materials such as ceramics and carbon-based nanostructures may especially absorb and dissipate heat from neighboring LED devices 210. Ceramics and carbon-based nanostructures absorb heat energy and emit it as far-infrared wavelength energy. Infrared radiation is a form of electromagnetic radiation with wavelengths longer than those at the red-end of the visible portion of the electromagnetic spectrum but shorter than microwave radiation. This wavelength range spans roughly 1 to several hundred microns, and is loosely subdivided—no standard definition exists—into near-infrared (0.7-1.5 microns), mid-infrared (1.5-5 microns), and far-infrared (5 to 1000 microns).

Ceramics which are inorganic oxides, nitrides, or carbides are considered as the most effective far-infrared ray emitting bodies. A number of studies on ceramic far-infrared ray emitting bodies have been reported including studies on zirconia, titania, alumina, zinc oxides, silicon oxides, boron nitride, and silicon carbides. Oxides of transition elements such as MnO₂, Fe₂O₃, CuO, CoO, and the like are considered more effective far-infrared ray emitting bodies. Other far-infrared ray emitting body includes carbon-based nanostructures such as carbon nanocapsules and carbon nanotubes, which also show a high degree of radiation activity. These materials are very close to a black body exhibiting a high degree of radiation activity throughout the entire infrared range. In certain embodiments, polymer layer 410 is pre-mixed with ceramics or carbon-based nanostructures that absorb the heat from nearby LED devices 210 and/or phosphors. These structures then dissipate the heat as far-infrared radiation. This characteristic may be used to allow heat to escape from LED devices 210 even when the LED devices are in a sealed enclosure without heat sinks or cooling fans. Of course, the addition of heat sinks or cooling fans heat may provide better heat dissipation.

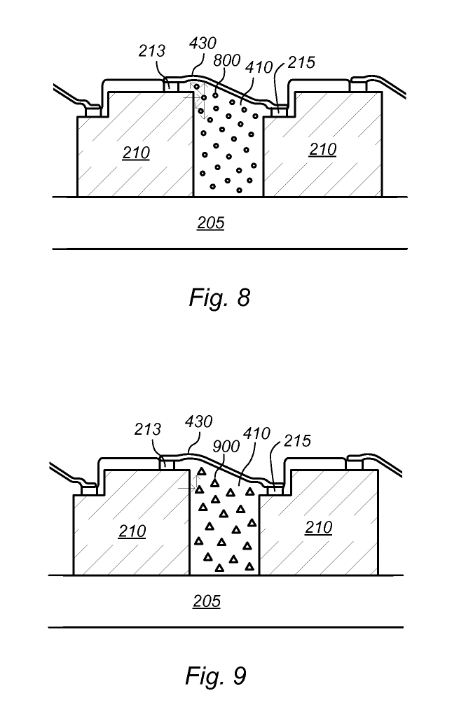

In certain embodiments, microsctructures are added to polymer material 410 to increase light extraction from LED devices 210 and LED array 200. The microstructures may, for example, be mixed with polymer material 410 before deposition of the polymer material on LED array 200. FIG. 8 depicts an embodiment of an LED array with spherical microstructures 800 in polymer material 410 filling the gap between two LED devices 210. FIG. 9 depicts an embodiment of an LED array with pyramid microstructures 900 in polymer material 410 filling the gap between two LED devices 210. While spherical and pyramid microstructures are shown in FIGS. 8 and 9, it is to be understood that other shapes may be contemplated. For example, tetrahedral or other polygonal microstructures may be used in polymer material 410 that provide similar advantages to the spherical and pyramid microstructures described herein.

In certain embodiments, microstructures 800 and/or microstructures 900 are transparent. Microstructures 800 and/or microstructures 900 may include edges or surfaces that reflect light. For example, as shown by the arrows in FIG. 8, spherical microstructures 800 may reflect (scatter) light from LED device 210 in multiple directions. As shown by the arrows in FIG. 9, pyramid microstructures 900, may also reflect light from LED device 210. As shown in FIG. 9, pyramid microstructures 900 may have a common orientation (e.g., one corner of each pyramid is oriented substantially vertically). Such an orientation may reflect light in a desired direction (e.g., upward out of the LED array). The desired direction may be the same direction as the orientation of the corner of each pyramid. In certain embodiments, a portion of the each pyramid microstructure 900 (e.g., a portion of the surface of each pyramid microstructure) may be magnetic such that a magnetic field applied to the LED array will orient the pyramid microstructures in the desired direction.

In certain embodiments, microstructures 800 and/or microstructures 900 in polymer material 410 are located only in the gap between LED devices 210 (e.g., there are no microstructures on top of the LED devices). If microstructures are in the polymer layer on top of LED devices 210, the microstructures may reflect back light emitted upward from the LED devices. Thus, having microstructures in the polymer layer only in the gap between LED devices 210 would limit light reflection to light emitted laterally from the LED devices 210. In certain embodiments, an LED structure without microstructures in the polymer layer above LEDs 210 is formed using steps similar to the embodiment depicted in FIG. 4B. For example, patterned mask 420 may be positioned over polymer layer 410 containing microstructures 800 and/or microstructures 900. Mask 420 may include additional openings at the locations over the LED devices to allow the removal of polymer layer 410 containing microstructures 800 and/or microstructures 900 above the LED devices. In some embodiments, an additional polymer layer is formed over LED devices 210 to form a polymer layer above the LED devices without microstructures.

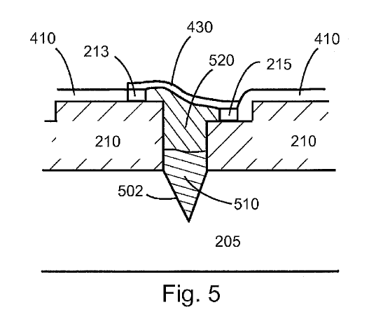

FIG. 5 illustrates an embodiment of an LED array with trench 502 formed in substrate 205 between two LED devices 210. Trench 502 is typically laser etched into the substrate during the formation of the gap between two LED devices 210 in order to allow more light to come out the lateral sides of the LED devices. As a result of the trench formation, light extraction efficiency of a whole LED chip that incorporates an array of LED devices 210 will be increased. The deeper trench 502 is, the higher the light extraction efficiency the LED chip may attain. Typically, a depth of trench 502 measured from an original surface of substrate 205 to the bottom of trench 502 is controlled at a range between 20 microns and 100 microns.

However, trench 502 may be more difficult to fill. Thus, in certain embodiments, as shown in FIG. 5, PMGI layer 510 is first deposited in trench 502 and then followed by SU-8 layer 520. PMGI layer 510 may have a better filling characteristic than SU-8 layer 520. For example, PMGI layer 510 may conform better to sloped sidewalls than SU-8 layer 520. SU-8 layer 520 deposited on top of the PMGI layer 510 may also serve as a barrier layer protecting the underneath PMGI layer 510 from reacting with developers in subsequent photoresist processes. One of such photoresist processes is forming interconnect 430 by metal sputtering in which a NR-7 patterning photoresist is used. The developer used with the NR-7 photoresist can react with PMGI layer 510 if not for the protection of SU-8 layer 520. However, if interconnect 430 is formed by a silver paste in a printing process, a single PMGI layer can be used for filling the entire gap, including trench 502, between the two LED devices 210. Using the single PMGI layer may save on processing costs.

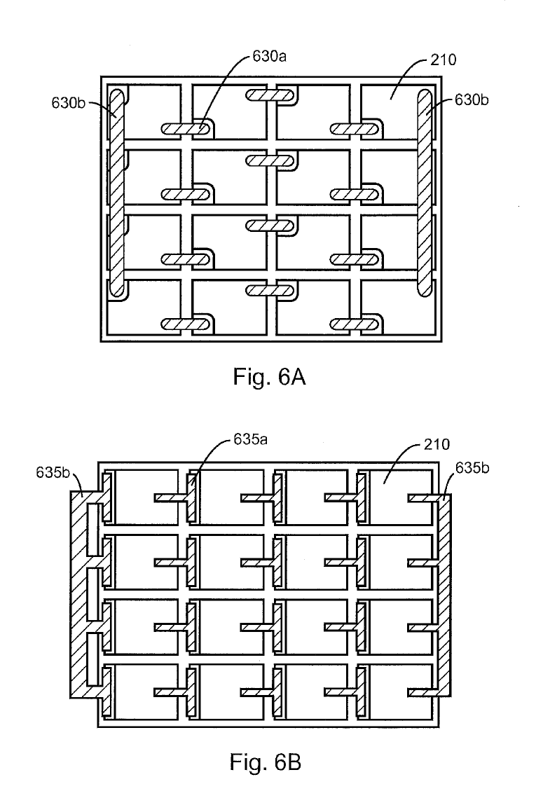

FIGS. 6A and 6B illustrate some alternative embodiments of patterns of interconnect 430. In some embodiments, as shown in FIG. 6A, interconnects 630a and 630b are moved to edges of LED devices 210 corresponding to relocations of electrode pads (not shown). In some embodiments, as shown in FIG. 6B, interconnects 635a and 635b are T-shaped to connect neighboring LED devices 210. Varying the interconnect patterns may reduce the area of the interconnects such that less light generated by the LED devices is shielded by the interconnects.

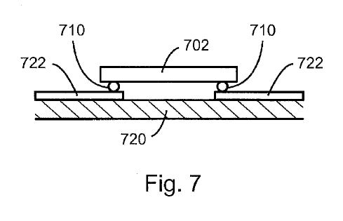

FIG. 7 illustrates an embodiment of LED chip 702 flip mounted on board 720. LED chip 702 may be produced through the embodiment of the process depicted in FIGS. 4A-4C (e.g., a plurality of LED devices 210 are formed on common substrate 205 (not shown in FIG. 7)). When substrate 205 is a sapphire substrate, which is highly transparent to light, LED chip 702 may be flip mounted on board 720. In such embodiments, substrate 205 of LED chip 702 is on the top and the plurality of LED devices 210 are below the substrate. Before the LED chip 702 is flip mounted on board 720, solder balls 710 are first formed on the terminals of LED chip 702. Then LED chip 702 is flipped over and placed on board 720 with solder balls 710 aligned to corresponding terminal interconnects 722. After a melting process, solder balls 710 bond LED chip 702 to board 720 through terminal interconnects 722. The flip-chip technology may yield the shortest board-level interconnects and better electrical characteristics. When multiple LED chips 702 are mounted on the same board 720, mounting density for the flip-chip mounting can be higher than conventional wire bonding. In addition, after LED chip 702 is flip mounted on board 720, the substrate (not shown in FIG. 7) on which the LED chip is grown can be removed for improved light emission.

It is to be understood the invention is not limited to particular systems described which may, of course, vary. It is also to be understood that the terminology used herein is for the purpose of describing particular embodiments only, and is not intended to be limiting. As used in this specification, the singular forms “a”, “an” and “the” include plural referents unless the content clearly indicates otherwise. Thus, for example, reference to “a device” includes a combination of two or more devices and reference to “a material” includes mixtures of materials.

Further modifications and alternative embodiments of various aspects of the invention will be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

What is claimed is:

1. A light-emitting-diode (LED) array comprising:
a first LED device having a first electrode;
a second LED device having a second electrode, wherein the first LED device and the second LED device are positioned on a common substrate;
at least one polymer material between the first LED device and the second LED device;
a plurality of microsctructures in the at least one polymer material; and
an interconnect, positioned on top of the at least one polymer material, electrically connecting the first electrode and the second electrode.

2. The LED array of claim 1, wherein the microstructures have sphere shapes or pyramid shapes.

3. The LED array of claim 1, wherein the plurality of microstructures are configured to reflect light from at least one of the first LED device or the second LED device during use.

4. The LED array of claim 1, wherein at least some of the plurality of microstructures are oriented to reflect light in a desired direction.

5. The LED array of claim 1, wherein the first LED device and the second LED device are connected in series or in parallel.

6. The LED array of claim 1, wherein the polymer material has a hydrophilic surface.

7. The LED array of claim 1, wherein the first LED device and the second LED device are separated by a gap, and the at least one polymer material substantially fills the gap.

8. The LED array of claim 7, wherein a trench is formed in the substrate below the gap.

9. The LED array of claim 8, wherein the gap and the trench are substantially filled with two or more polymer materials forming a multi-layered structure.

10. A method for forming a light-emitting-diode (LED) array, comprising:
forming an LED structure on a substrate;
dividing the LED structure into at least a first LED device and a second LED device;
depositing at least one polymer material between the first LED device and a second LED device, wherein the at least one polymer material comprises a plurality of microstructures; and
forming an interconnect on top of the at least one polymer material to electrically connect a first electrode of the first LED and a second electrode of the second LED.

11. The method of claim 10, wherein the microstructures have sphere shapes or pyramid shapes.

12. The method of claim 10, wherein the plurality of microstructures are configured to reflect light from at least one of the first LED device or the second LED device during use.

13. The method of claim 10, further comprising orienting at least some of the plurality of microstructures to reflect light in a desired direction.

14. The method of claim 10, further comprising connecting the first LED device and the second LED device in series or in parallel.

15. The method of claim 10, further comprising forming a gap between the first LED device and the second LED device, and depositing the at least one polymer material over the LED structure and substantially filling the gap.

16. The method of claim 15, further comprising removing, before forming the interconnect, the at least one polymer material over the LED structure.

17. The method of claim 10, further comprising transforming a surface of the polymer material from a hydrophobic surface to a hydrophilic surface using an oxygen plasma.

18. The method of claim 10, further comprising pre-mixing the polymer material with the plurality of microsctructures.

19. The method of claim 10, further comprising forming a trench in the substrate below the gap.

20. The method of claim 10, further comprising substantially filling the gap and the trench with two or more polymer materials forming a multi-layered structure.
